(19) United States
(12) Patent Application Publication
(10) Pub. No.: US 2006/0001124 A1
(43) Pub. Date: Jan. 5, 2006

(54) Low-loss substrate for high quality components

(75) Inventors: Farrokh Ayazi, Atlanta, GA (US); Mina Raieszadeh, Atlanta, GA (US)

Correspondence Address: Kenneth W. Float, 2095 Hwy. 211 NW, # 2F, Braselton, GA, 30517, US

(73) Assignee: Georgia Tech Research Corporation

(21) Appl. No.: 11/168,066

(22) Filed: Jun. 28, 2005

Related U.S. Application Data
(60) Provisional application No. 60/585,496, filed on Jul. 2, 2004.

(51) Int. Cl. H01L 29/00

(52) U.S. Cl. 257/531

(57) ABSTRACT

Methods and apparatus providing high quality factor (Q) components on low loss substrates. A substrate is fabricated having a plurality of substrate support elements. A bridging layer is formed on the substrate that is supported by the support elements. A component is formed on the bridging layer. CMOS-compatible processing of silicon substrates may be used. One or more cavities comprising high aspect-ratio trenches may be formed using a low-temperature fabrication sequence which reduces the high-frequency losses in silicon at RF frequencies. The cavities (trenches) are subsequently bridged over or refilled with a dielectric to close the open areas and create a rigid low-loss structure. The structures mechanically-robust and are compatible with any packaging technology. An exemplary one-turn 0.8 nH inductor fabricated on trenched silicon support elements exhibited a very high peak Q of 70.6 at 8.75 GHz with a self-resonant frequency larger than 15 GHz.

### BACKGROUND

The present invention relates generally to substrates and substrate fabrication methods, and more particularly, to low-loss substrates that permit fabrication of high quality factor (Q) components thereon and related fabrication methods.

High-Q integrated inductors can improve the performance and integration-level of RF integrated circuits while reducing their power consumption and cost. Inductors are vastly used in voltage controlled oscillators, low noise amplifiers, power amplifiers, mixers, filters and matching networks. However, on-chip inductors in commercially available CMOS processes exhibit poor Q's (<15) due to the high-frequency loss of standard silicon substrate and ohmic loss of thin metal layers. While metal loss can be reduced by using thick high-conductivity metals, the loss of silicon substrate has remained the major barrier in reaching Q's comparable to that of off-chip inductors on silicon. The most effective way of reducing the metal loss is through electroplating a thick Cu layer.

Micromachining techniques have been utilized to reduce the substrate loss and increase the Q (see M. Raieszadeh, P. Monajemi, S. Yoon, J. Laskar, F. Ayazi, “High-Q Integrated Inductors on Trenched Si Islands,” IEEE International Conference on MEMS, January 2005, pp. 199-202). Previously reported techniques include the use of thick isolating oxide layer (see H. B. Erzgraber, et al., “A Novel Buried Oxide Isolation for Monolithic RF Inductors on Silicon,” IEEE Electron Device Meeting, 1998, pp. 535-539, and C. M. Nam and Y. S. Kwon, “High-Performance Planar Inductor on Thick Oxidized Porous Silicon (OPS) Substrate,” IEEE microwave guided wave lett., vol. 7, No. 8, August 1997), use of porous silicon to increase the substrate resistance (see A. S. Royet, et al., “On the investigation of spiral inductors processed on Si substrates with thick porous Si layer,” European Solid-State Device Research, September 2003, pp. 111-114), suspension of the inductors (see H. Jiang, et al., “On-chip Spiral Inductors Suspended over Deep Copper-Lined Cavities,” IEEE Tran. MTT, vol. 48, No. 12, December 2000, pp. 2415-2423, Jun-Bo Yoon, et al., “CMOS-Compatible Surface-Micromachined Suspended- Spiral Inductors for Multi-GHz Silicon RF ICs,” IEEE Electron Device Lett., vol. 23, No. 10, October 2002, pp. 591-593, and R. P. Ribas, et al., “Micromachined Microwave Planar Spiral Inductors and Transformers,” IEEE MTT, vol. 48, No. 8, August 2000, pp. 1326-1335), use of 3-D structures such as toroids and self assembled solenoids (see D. H. Weon, et al., “High-Q Integrated 3-D Inductors and Transformers for High Frequency Applications,” IEEE MTT-S Digest, 2004, pp. 887-880, C. L. Chua, et al., “Out-of-Plane High-Q Inductors on Low-Resistance Silicon,” IEEE J. Microelectromechanical Systems, vol. 12, No. 6, December 2003, pp. 989-995, and Y. H. Joung, et al., “Integrated inductors in the chip-to-board interconnect layer fabricated using solderless electroplating bonding,” IEEE MTT-S Int. Microwave Symp. Dig., 2002, pp. 1409-1412), and use of thick low-K dielectrics (see S. Dalmia, F. Ayazi, et al., “Design of Inductors in Organic Substrates For 1-3GHz Wireless Application,” IEEE MTT-S, vol. 3, June 2002, pp. 1405-1408, and G. J. Carchon, et al., “High-Q Above-IC Inductors and Transmission Lines—Comparison to Cu Back-End Performance,” IEEE Electron Components and Technology Conference, 2004, pp. 1118-23). Suspension may cause susceptibility to shock and vibrations and can complicate die packaging. Quality factor of 3-D and suspended inductors may also drop due to the encapsulating material used in packaging (see Y. S. Choi, et al., “Encapsulation of the Micromachined Air-Suspended Inductors,” IEEE MTT-S Digest, 2003, pp. 1637-1640). The use of thin (≦20 μm) low-K dielectric materials alone is not sufficient to effectively reduce the substrate loss.

In general, typical quality factors (Q) associated with conventional devices formed on substrates is on the order of 10 or less. There is a need for substrates that permit fabrication of high quality factor (Q) components thereon.

U.S. Pat. No. 6,274,920 discloses, as indicated by its title, an “Integrated inductor device and method for fabricating the same.” As is stated in the “Summary of the Invention” section, U.S. Pat. No. 6,274,920 discloses that:

“It is, therefore, an object of the present invention to provide an integrated inductor device and a method for fabricating the same, in which a parasitic capacitance and a magnetic coupling can be reduced an integrated device.

In accordance with an aspect of the present invention, there is provided a method for fabricating an inductor device, comprising the steps of: a) forming a plurality of trenches in a substrate by selectively etching the substrate; b) implanting dopants into sidewalls and bottom portion of each trench; c) forming an oxide layer by oxidizing the trenches and the substrate and simultaneously forming a doped layer on a region neighboring to the substrate by diffusing the dopants into the substrate; and d) forming a dielectric layer on the resultant structure to fill the entrance of the trenches, thereby forming air-gap layers in the trenches.

In accordance with another aspect of the present invention, there is provided an integrated inductor device which is formed by integrating an inductor on a substrate, comprising; a trench structure formed in the substrate; a dielectric layer formed on the resultant structure, so that an entrance of the trench structure is filled to thereby form an air gap layer between the trench structure and the dielectric layer; a doped layer formed in a region neighboring to the trench structure; an contact hole for exposing the doped layer; and an electrode, wherein the electrode is connected to the doped layer through the contract hole.”

Thus, while U.S. Pat. No. 6,274,920 discloses an integrated inductor device, this device includes “a doped layer formed in a region neighboring to the trench structure; a contact hole for exposing the doped layer; and an electrode, wherein the electrode is connected to the doped layer through the contract hole.”

Furthermore, it is stated in U.S. Pat. No. 6,274,920 at column 4, lines 57-62 that “As mentioned above, by forming the air gap layers 15 in the direction perpendicular to the region overlapping with the inductor and the doped layer 13A having a conductivity type opposite to that of the substrate, the parasitic capacitance due to the substrate loss is remarkably reduced. Thus, the capacitive coupling can be effectively prevented.”

It is also stated in U.S. Pat. No. 6,274,920 at column 5, lines 28-33 “As described in an embodiment of the present invention, by forming the air-gap layers 33 in the direction perpendicular to the region overlapping with the inductor and the doped layer 31 having a conductivity type opposite to that of the substrate, the parasitic capacitance due to the substrate loss is remarkably reduced. Thus, the capacitive coupling can be effectively prevented.”

Thus, it is clearly stated in U.S. Pat. No. 6,274,920 that forming the air-gap layers in a direction perpendicular to the region overlapping with the inductor in conjunction with a doped layer having a conductivity type opposite to that of the substrate results in a reduction of the parasitic capacitance, and capacitive coupling can be effectively prevented.

Furthermore, it is stated in U.S. Pat. No. 6,274,920 at column 5, lines 7-10 with regard to FIGS. 2A and 2B, for example, that “the inductor device includes a plurality of trenches, whose sidewalls and bottom portion are made up of an oxide layer 14. “The other disclosed embodiments of the inductor device also include an oxide layer (32, 52) that defines the trenches.

U.S. Pat. 6,274,920, at column 4, lines 4-18 also states that “Referring to FIG. 3E, an oxide layer 14 is formed by a wet oxidation of the silicon substrate 10A and 10B. At this time, the wet oxidation is performed at a temperature of 90° C. to 1100° C. in a furnace maintaining a H₂/O₂ atmosphere. Thus, this is a high temperature process that is not compatible with conventional CMOS processing. Furthermore, having oxidized trenches of large area as is the case in U.S. Pat. No. 6,274,920, introduces stress to the substrate and causes curvature in the substrate in which the trenches are made.

The present inventors have determined that a doped layer having a conductivity type opposite to that of the substrate is not required as part of the integrated inductor device as taught by U.S. Pat. No. 6,274,920 in order to have a structure with reduced capacitive losses. Furthermore, it would be desirable to have a low-temperature and low-stress fabrication process that is compatible with conventional CMOS and post-CMOS processing.

### BRIEF DESCRIPTION OF THE DRAWINGS

The various features and advantages of the present invention may be more readily understood with reference to the following detailed description taken in conjunction with the accompanying drawings, wherein like reference numerals designate like structural elements, and in which:

FIG. 1 illustrates an exemplary high quality factor (Q) component integrated on a substrate having plurality of islands separated by trenches, which here is referred to as perforated substrate;

FIG. 1a illustrates an exemplary high quality factor (Q) component integrated on a perforated substrate that is refilled with a low loss material;

FIGS. 2a-2e illustrate an exemplary process flow for fabricating an exemplary high quality factor (Q) component on a substrate;

FIGS. 2f-2h illustrate additional processing that may be performed to fabricate an exemplary high quality factor (Q) component on a substrate;

FIGS. 2g′ and 2g″ show encapsulated versions of the apparatus;

FIG. 3 shows a portion of an exemplary one turn inductor formed on top of a perforated silicon substrate;

FIG. 4 shows a portion of another exemplary one turn inductor formed on top of a perforated silicon substrate, along with an enlarged view of trenches formed in the substrate;

FIG. 5 is a graph showing measured Q versus frequency of an inductor fabricated on a perforated silicon substrate showing dependency of Q on trench depth;

FIG. 6 shows a portion of an exemplary perforated silicon substrate that is refilled with a low loss material;

FIG. 7 is a graph showing measured Q of a one turn inductor fabricated on a perforated silicon substrate, showing the high embedded and de-embedded Q;

FIG. 7a is a graph showing a comparison between measured Q of a 0.9 nH inductor 14 fabricated on oxide islands and Avatrel refilled trenched silicon islands;

FIG. 8 is a graph showing measured Q of identical inductors fabricated on 1) perforated silicon substrate without refilling, 2) perforated silicon substrate that are refilled with Avatrel, and 3) silicon substrate passivated with 20 μm thick oxide;

FIG. 9a is a top view of another exemplary one turn inductor formed on top of a perforated substrate showing that the trenched area can be solely beneath the conductive track and the pads; and

FIG. 9b is a graph showing measured Q versus frequency for the exemplary inductor shown in FIG. 8a with various trenched area.

### DETAILED DESCRIPTION

Any mechanism that converts the electromagnetic energy into heat is considered as loss. For inductors, the only desirable source of energy storage is a magnetic field and hence any source of electric energy storage is considered as parasitic. As a result, the Q of an inductor can be expressed as follow:

$$Q = 2 π \frac{peak magnetic energy - peak electric energy}{Energy dissipated per cycle of oscillation} \qquad ( 1 )$$

Two independent loss mechanisms are present in inductors: the metal loss and the substrate loss. Therefore, the unloaded Q of an inductor can be expressed by (from P. Arcioni, et al., “An Innovative Modelization of Loss Mechanism in Silicon Integrated Inductor,” IEEE Trans. Circuit and Systems, vol. 46, No. 12, 1999, pp. 1453-1460)

$$\frac{1}{Q} = \frac{1}{{Q}_{substrate}} + \frac{1}{{Q}_{metal}} \qquad ( 2 )$$

where Q_{substrate} and Qₘₑₜₐₗ represent the substrate loss and the ohmic loss of metal strips, respectively.

At very low frequencies, the DC series resistance of the metal layers is the dominant Q-limiting mechanism. At higher frequencies, where the skin depth is less than half the thickness of the conductor, skin and proximity effects reduce the effective area of current flow and thus further limit the Q. At higher frequencies, loss mechanisms present in the substrate sets the lower limit on the Q. To obtain high-Q inductors, the effect of both substrate and metal loss should be effectively suppressed.

At RF frequencies, induced currents in the substrate limit Q_{substrate} by converting the electromagnetic energy into heat. AC current flowing in the inductor produces a magnetic field H. If a static potential difference of V exists between the inductor and the ground plane, the Maxwell equations can be written as follow (from D. M. Pozar, Microwave engineering, Amherst, Mass.: John Wiley & Sons, 1998):
∇×H=jωεE+σE, μH=∇×A (3)
∇×E=−jωμH, E=−∇V−jωA (4)
where A is the vector potential, σ and ε represent the substrate conductivity and permittivity, respectively; ω is the angular frequency and μ is the substrate permeability. Substituting equation 4 into equation 3 gives:
∇×H=−jωε∇V−σ∇V+ω²εA−jσωA (5)

If −jωA is the magnetically-induced electric field E′ penetrating into the substrate, the overall current density in the substrate can be found from:
J=jωε′(−∇V+E′)+σ(−∇V+E′)+ωε″(−∇V+E′) (6)
where ε′ and ε″ are the real and imaginary parts of substrate permittivity, respectively (loss tangent=tan δ=ε″/ε′).

The first term of right hand side of equation 6 represents the capacitive loss of the substrate. The second term corresponds to the conduction loss (−σ∇V) and the eddy current loss (σE′). The last term (ωε″(−∇V+E′)) denotes the electrically- and magnetically-induced dipole loss, which becomes dominant at high frequencies.

For low-resistivity substrates such as CMOS-grade silicon, the electrically-induced current density (−σ∇V) and losses associated with the eddy current (σE′) dominates over the dipole loss. However, for high-resistivity substrates the dipole loss is the determining loss mechanism.

Therefore, disrupting the path of dissipating currents by vertically-slicing the substrate with deep high-aspect-ratio trenches reduces the conduction and eddy current losses as well as the capacitive and dipole losses, which in turn increases the Q. Exemplary two low-temperature approaches may be used to create a rigid and smooth surface on the trenched areas for subsequent fabrication of components. These approaches include bridging-over the trenches) with a plasma enhanced chemical vapor deposited (PECVD) dielectric layer (e.g. SiO₂), and filling the trenches with a material (e.g., Avatrel polymer).

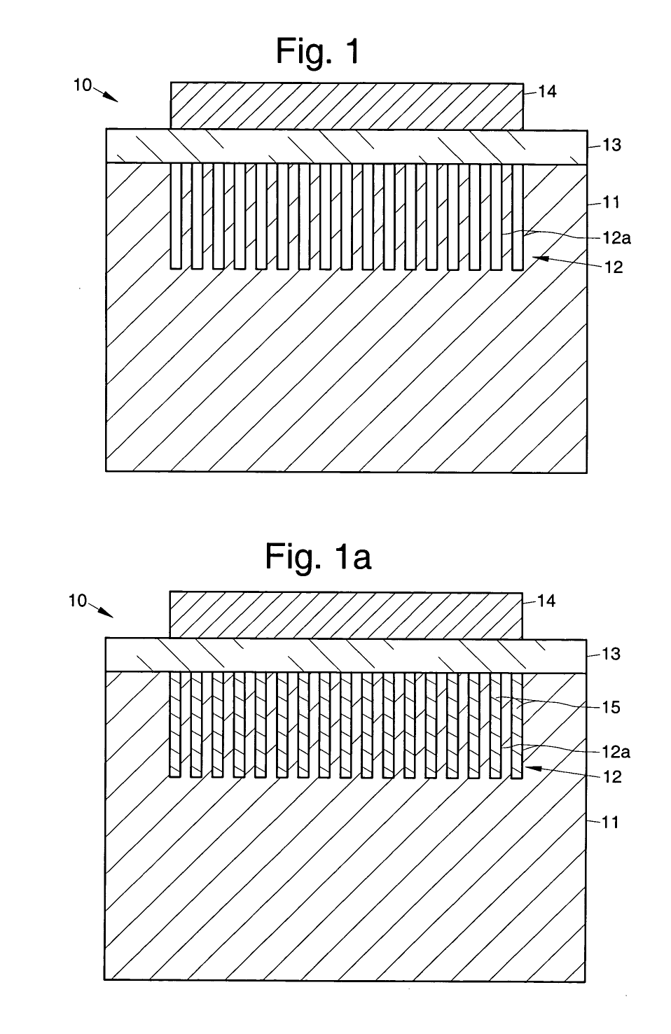

Referring now to the drawing figures, FIG. 1 illustrates apparatus 10 comprising an exemplary high quality component 14 formed on a substrate 11 having islands 12 separated by trenches 12a or one or more deep cavities 12a forming pillars 12 or posts 12 (i.e., forming a perforated substrate 11). The islands 12, pillars 12, or posts 12 comprise support elements 12. A bridging layer 13, such as a dielectric layer for example silicon dioxide (SiO₂), is formed over the perforated substrate 11 to cover the trenches 12a and to planarize the surface of the perforated substrate 11. In general, the component 14 comprises conductive traces and possibly other elements formed on the bridging layer 13 that defines the component 14.

Reduced to practice embodiments of the apparatus 10 include components 14 comprising inductors and capacitors having high quality factors (Q), which are formed on low loss substrate 11 having plurality of trenches 12a bridged over with a silicon dioxide bridging layer 13. However, the concepts described herein permit fabrication of many types of components 14 other than inductors and capacitors, including other passive structures. In particular, the concepts described herein may be used to fabricate inductors, transmission lines, filters embodying capacitors and inductors, antennas, micromechanical switches, transformers, baluns and tunable or fixed capacitors, for example. Also, the types of substrates 11 on which the components 14 may be fabricated include silicon, glass, silicon carbide, sapphire, ceramic, polymer, and organic substrates, for example. Also, the substrate 11 may be multilayer, wherein the islands 12 are made in the top layer of the substrate 11 and can extend into the underlying layers. Thus, it is to be understood that the inventions described herein are not limited to the specifically disclosed inductor or capacitor embodiments.

Furthermore, the manner in which low loss substrates 11 are produced are not limited to fabrication of trenches 12a to form the perforated substrate 11. For example, posts or pillars may be formed in the substrate 11, or the substrate 11 may be fabricated to have a structure that looks like a waffle, for example. Thus, any structure may be formed in the substrate 11 that removes portions of the substrate 11 to reduce loss, while providing enough structure to allow fabrication of the bridging layer 13 that bridges over the remaining non-removed structure (i.e., the islands 12) to form a surface over the substrate 11 on which the components 14 may be formed.

The main approach employed to produce reduced to practice embodiments of the apparatus 10 is by bridging over open areas of the substrate 11 (i.e., trenches 12a) by depositing a thin PECVD SiO₂ layer as the bridging layer 13. The required film thickness to bridge over the open areas (trenches 12a) comprising the perforated silicon substrate 11 and create a smooth surface is in the order of the width of the trenches 12a. The width of the openings (here trenches) should be optimized for low substrate loss and reasonable bridging SiO₂ thickness. For a perforated silicon substrate 11 with repeated trench width of 2 μm and silicon width of 2 μm, the required thickness of the PECVD SiO₂ dielectric bridging layer 13 is ˜3 μm.

As an alternative, the perforated substrate 11 may be refilled with a (low loss) material 15 to create a rigid substrate 11. FIG. 1a illustrates apparatus 10 comprising another exemplary high quality component 14 formed on a perforated substrate 11. In this embodiment, the perforated substrate 11 are refilled with low loss material 15. An exemplary low loss material 15 is Avatrel 2000P polymer, available from Promerous Inc.

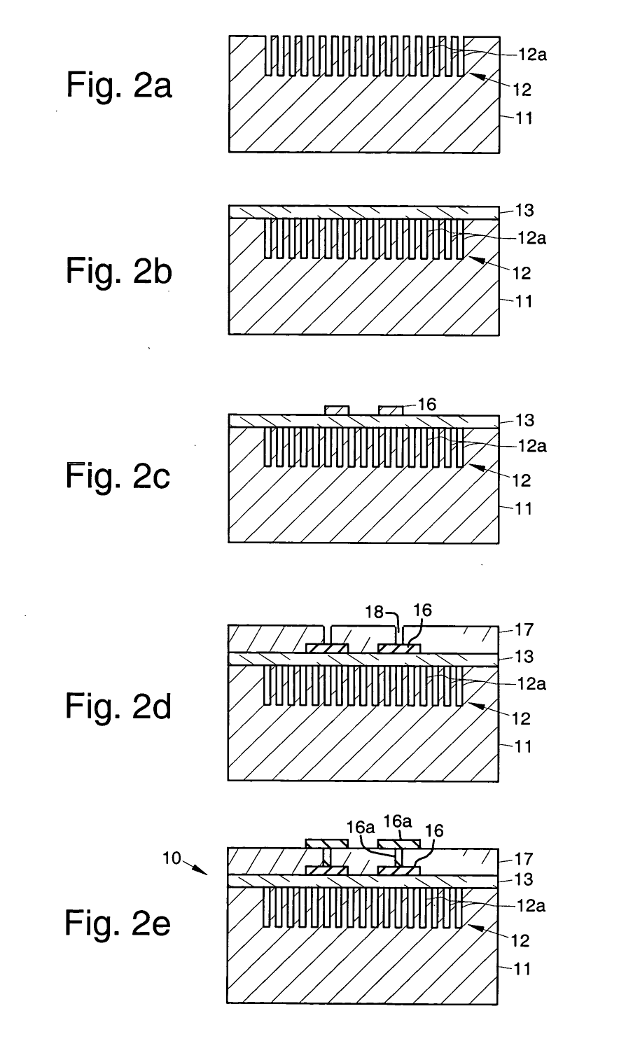

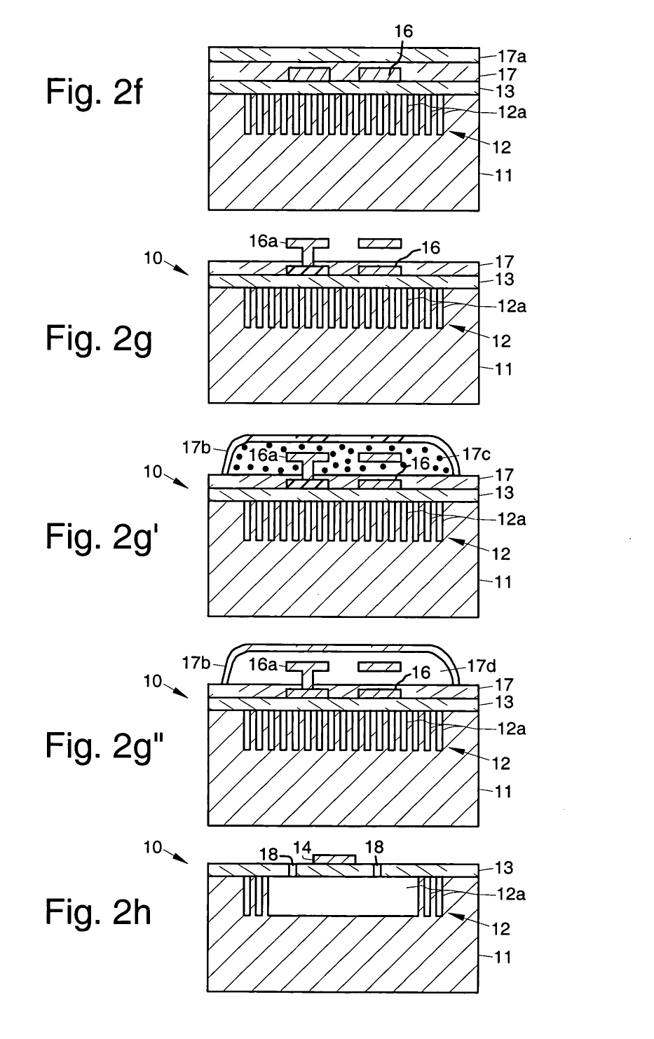

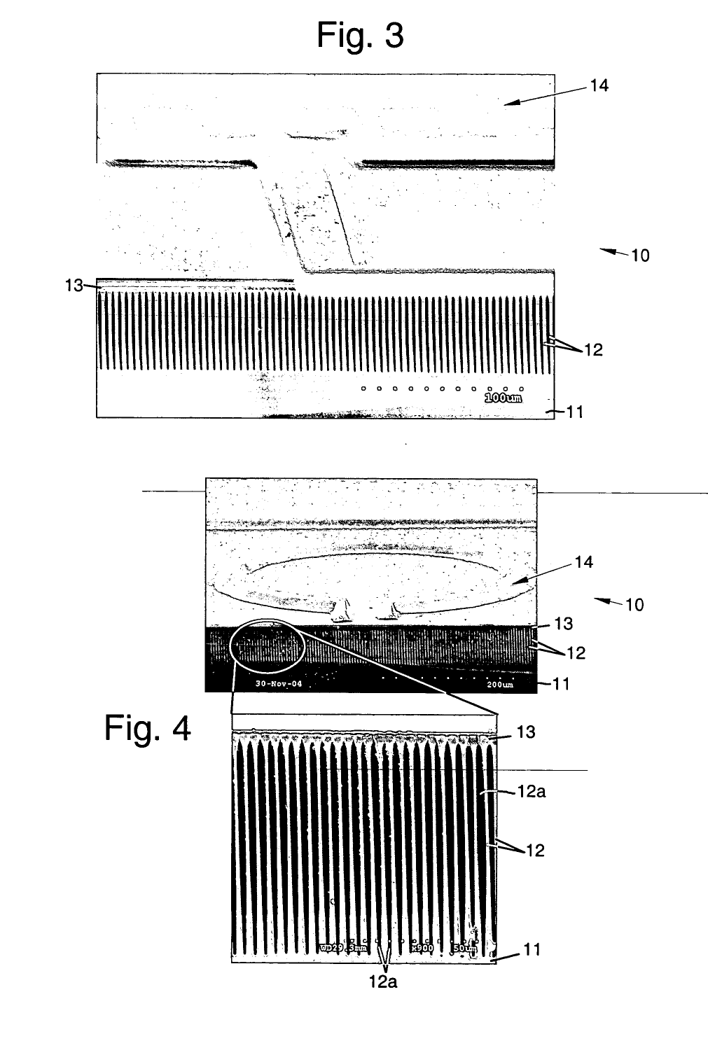

FIGS. 2a-2e illustrate an exemplary process flow for fabricating an exemplary high quality factor (Q) inductor 14 on a substrate 11. This exemplary fabrication process were used to create the reduced to practice embodiments of the apparatus 10 discussed herein. This exemplary fabrication process produces copper (Cu) inductors on perforated silicon substrate 11.

As is shown in FIG. 2a, deep high-aspect-ratio (30:1) trenches 12a are etched into a silicon substrate 11 using a deep reactive ion etching process, known as the Bosch process. As is shown in FIG. 2b, a 2-3 μm thick PECVD SiO₂ bridging layer 13 is then deposited at 300° C. to cover openings (trenches 12a) and lower substrate parasitic capacitances. As is shown in FIG. 2c, a first (lower) conductive layer 16 is deposited on top of the PECVD SiO₂ bridging layer 13 which may be a 1.5 μm thick Chrome (Cr)—Cu—Cr layer. To isolate the lower conductive layer 16 from a second (upper) conductive layer 16a, as is shown in FIG. 2d, a 2 μm thick PECVD SiO₂ layer 17 is deposited at 300° C. and vias 18 are opened. A 1000A° seed layer of Cr—Cu is then sputter deposited, followed by spin-coating and patterning of an electroplating mold for fabricating the second (upper) conductive layer 16a. Finally, as is shown in FIG. 2e, thick layer of Cu is electroplated to form the second (upper) conductive layer 16a, and the photoresist and seed layer are removed.

FIGS. 2f-2h illustrate additional processing that may be performed to fabricate an exemplary high quality component 14 on a substrate 11. As is shown in FIGS. 2f-2g, the processing may occur after the processing performed in FIGS. 2a-2c to produce a suspended component 14. As is shown in FIG. 2f, after the bridging layer 13 is formed, two subsequent layers 17, 17a are formed, a first dielectric layer 17 that is deposited on the bridging layer 13 to the top of the lower conductive layer 16, and a second sacrificial layer 17a that is deposited on top of the first dielectric layer 17. As is shown in FIG. 2g, after the upper conductive layer 16a is formed on top of the sacrificial layer 17a, the sacrificial layer 17a is removed to suspend the upper conductive layer 16a above the lower conductive layer 16. This structure may be used to form a switch, for example. An alternative way, which is not shown, is that after forming the high quality component 14, as shown in FIG. 2e, the dielectric layer 17 is removed to suspend the upper conductive layer 16a above the first conductive layer 16 and the perforated substrate 11.

In many embodiments, the component 14 may be hermetically or non-hermetically encapsulated as shown in FIG. 2g′. Where the encapsulating material 17b does not come into contact with the component 14. An example of this packaging is demonstrated by Monajemi et al. “A Low Cost Wafer-Level MEMS Packaging Technology,” Proc. IEEE Micro Electro Mechanical Systems Conference (MEMS'05), Miami, Fla., January 2005, pp. 634-637, in which the encapsulating material 17b is supported by a sacrificial polymer 17c. Referring to FIG. 2g″, the sacrificial polymer 17c is thermally decomposed to create an air, vacuum, or some gas 17d cavity above the component 14.

FIG. 2h shows an alternative arrangement for the substrate 11 having plurality of islands 12, named perforated substrate 11. In this case, after the processing is performed with reference to FIGS. 2a and 2b, one or more vias 18 are formed in the bridging layer 13. Some of the islands 12 are then etched away using an isotropic etching process to remove them. Some of the islands 12 remain so that the bridging layer 13 and other relevant structures are adequately supported and the parasitic capacitance under supporting pads and capacitors are reduced. This enhances the quality factor of the apparatus 10.

Exemplary embodiments of the apparatus 10 may have substrates 11 on the order of 500 microns thick, with high aspect ratio (on the order of 5:1 to 100:1) trenches or deep cavities 12a on the order from 2 to 200 microns deep. The trenches 12a are nominally 2-3 μm wide and the islands 12 are nominally 1-2 μm wide. Thus, relatively wide trenches 12a and thin islands 12 are formed. The bridging layer 13 is nominally 2-3 μm thick. Typically, trenches 12a are formed that remove as much of the substrate 11 as is possible, while keeping enough structure to support the bridging layer 13. More of the substrate 11 may be removed if the trenches 12a are refilled with low loss material 15. The trenches 12a are etched to a depth that is below any eddy current lines that may be generated, for best result. This disrupts the flow of eddy current through the substrate 11, which reduces the losses caused by the substrate 11.

Increasing the undercut of substrate 11 during etching of the trenches 12a further reduces the substrate loss by decreasing the equivalent relative permittivity and conductivity of the substrate 11. Therefore, even in the case of non-conductive substrates 11 such as glass, etching the trenches 12a lowers the substrate 11 loss by reducing the substrate 11 permittivity. FIG. 4 shows a component 14 comprising a 0.8 nH inductor 14 on 70 μm deep perforated silicon substrate 11. As shown in FIG. 4, the width of the trenches 12a in the bulk of the trenched region is reduced to about 1 μm, while the width of the openings (trenches 12a) is kept at the order of 2 μm, to avoid deposition of a thicker bridging layer 13 to cover the trenches 12a.

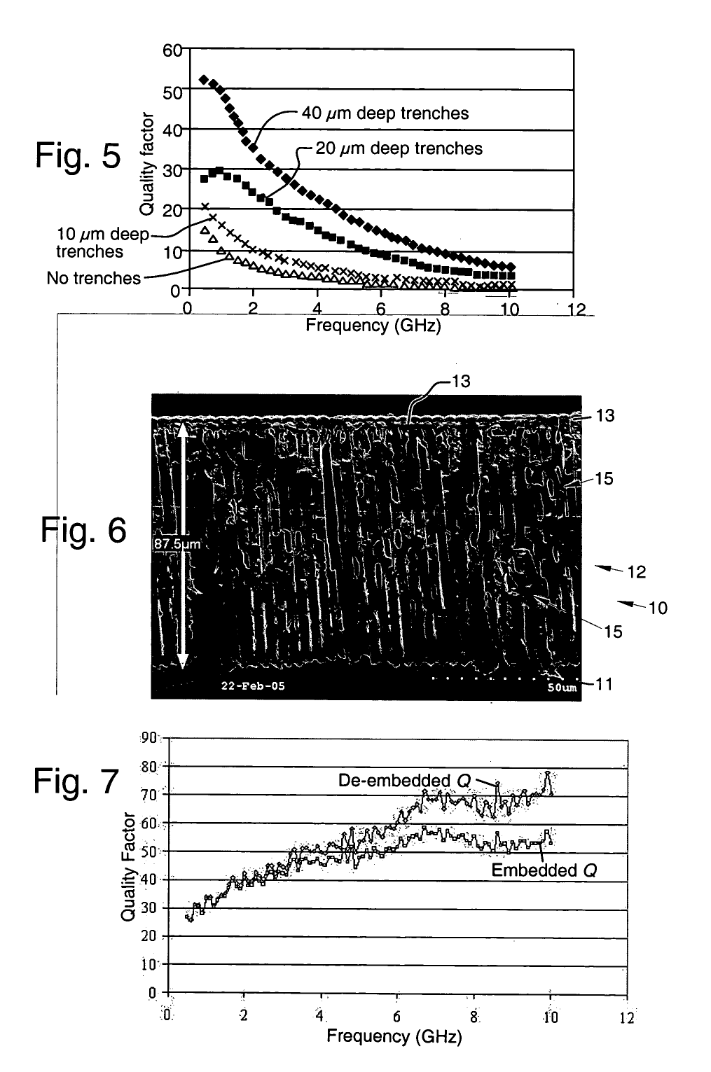

FIG. 5 is another notable result, which specifies the role of the trench depth in reducing the substrate loss. In particular, FIG. 5 illustrates measured Q vs. frequency showing dependency of Q on trench depth. The Q of a 1.07 nH inductor on 40 μm deep perforated silicon substrate 11 is 4× higher than the similar design (with identical metal thickness) fabricated on 10 μm deep perforated silicon substrate 11 (Q_{40 μm}=32 @2.4 GHz).

As was discussed above with reference to FIG. 1a, the trenches 12a may be refilled with a low loss (low-K) dielectric material 15 to create a rigid substrate 11. FIG. 6 shows a cross sectional view of 90 μm deep perforated silicon substrate 11 that are refilled by spin-coating of Avatrel dielectric material 15. The refilled perforated silicon substrate 11 is successively coated with a thin PECVD SiO₂ bridging layer 13 (˜1 μm) in order to promote the adhesion of consecutive layers to the substrate 11. Subsequent processing steps are as shown and discussed with reference to FIGS. 2b-2e.

Rectangular and circular type reduced to practice inductors of various dimensions have been fabricated and tested on trenched silicon substrates 11. On-wafer S-parameter measurements were carried out using an hp8517B vector network analyzer and ground-signal-ground Cascade micro-probes. Pad-only characteristics were measured on open pad structures. The pads parasitic capacitance were then de-embedded from the overall inductor characteristic by subtracting the Y-parameters of the pads from the Y-parameters of the embedded inductors (see S. A. Wartenberg, RF measurement of die and packaging, Artech House, 2002). Inductance and Q are calculated from:

$$L = \frac{Im ( 1 / {Y}_{11} )}{2 \times π \times f} Q = \frac{Im ( 1 / {Y}_{11} )}{Re ( 1 / {Y}_{11} )} \qquad ( 8 )$$

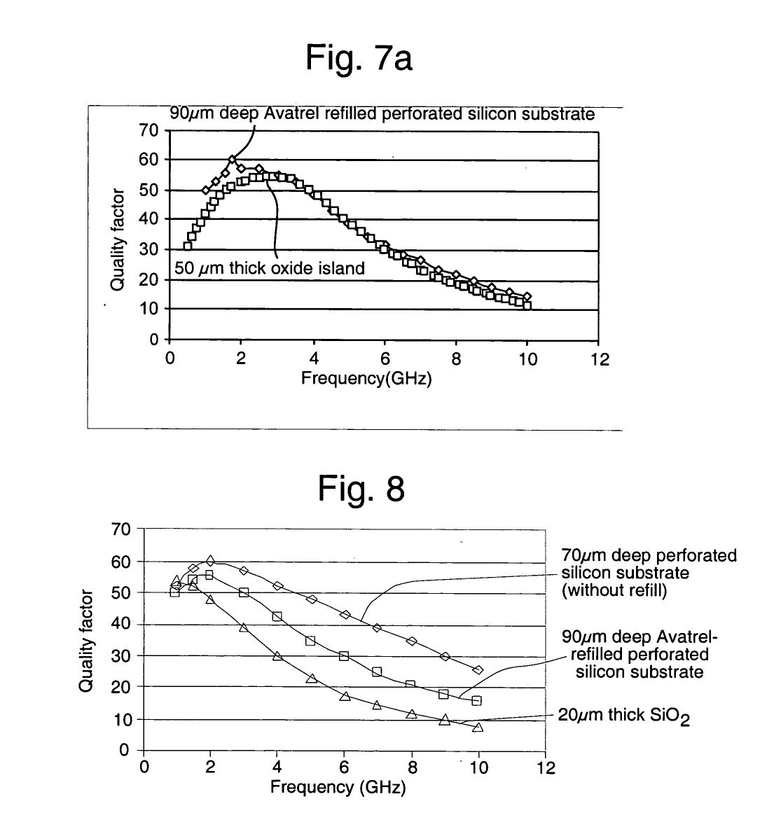

FIG. 7 shows the embedded and de-embedded Q and inductance of an inductor 14 fabricated on 70 μm deep perforated silicon substrate 11 with silicon resistivity of 10 Ω.cm (the SEM picture is shown in FIG. 4). The quality factor is over 50 in the 5-10G Hz range with a maximum of 70.6 at 8.75 GHz. The self resonant frequency of this exemplary inductor 14 is much higher than 15 GHz.

The significant effect of trenching the silicon substrate 11 in improving the Q is revealed by comparing the loss of a perforated silicon substrate 11 with the loss of a standard silicon substrate coated with a thick dielectric material. Similar performance is observed in the low frequency regime, where Q is limited to Qₘₑₜₐₗ. At high frequencies, however, the Q of an inductor 14 fabricated on perforated silicon substrate 11 is 2× higher than the Q of identical inductors on a standard silicon substrate passivated with 20 μm thick dielectric material, showing the remarkable effect of disrupting the pass of current on the Q.

Inductors 14 fabricated on perforated silicon substrate 11 have high embedded-Q in contrast to the suspended inductors reported in the literature (see Jun-Bo Yoon, et al., “CMOS-Compatible Surface-Micromachined Suspended-Spiral Inductors for Multi-GHz Silicon RF ICs,” IEEE Electron Device Lett. vol. 23, No. 10, October 2002, pp. 591-593). This is because the parasitic capacitances of pads are reduced simultaneously by reduction of the substrate loss underneath the pads.

The performance of an inductor 14 formed on an Avatrel refilled 90 μm deep perforated silicon substrate 11, having a maximum Q of 60 at 1.75 GHz was compared to an identical inductor fabricated on 50 μm thick embedded oxide island, which is illustrated in FIG. 7a. FIG. 7a is a graph showing a comparison between measured Q of a 0.9 nH inductor 14 fabricated on oxide islands and Avatrel refilled trenched silicon islands. The thick oxide island is realized by oxidizing the islands 12 left in between the trenches 12a at 1000° C. (see H. B. Erzgraber, et al., “A Novel Buried Oxide Isolation for Monolithic RF Inductors on Silicon,” IEEE Electron Device Meeting, 1998, pp. 535-539). The performance of the two devices are almost equal, resulting in similar Q values at high frequencies (f≧3 GHz). While the maximum processing-temperature of the Avatrel refilled perforated silicon substrate 11 is 160° C., making it a CMOS compatible low-loss substrate 11.

FIG. 8 is a graph showing measured Q of an inductor fabricated on an Avatrel-refilled perforated silicon substrate 11, 70 μm deep perforated silicon substrate 11, and 20 μm thick PECVD SiO₂ coated silicon substrate 11. As is shown in FIG. 8, the Q of the inductor 14 on 70 μm deep perforated silicon substrate 11 is 2.5× higher than the Q of the identical inductor 14 on 20 μm thick SiO₂ coated standard silicon substrate 11 at high frequencies (f>4 GHz), where the substrate loss is the dominant loss mechanism.

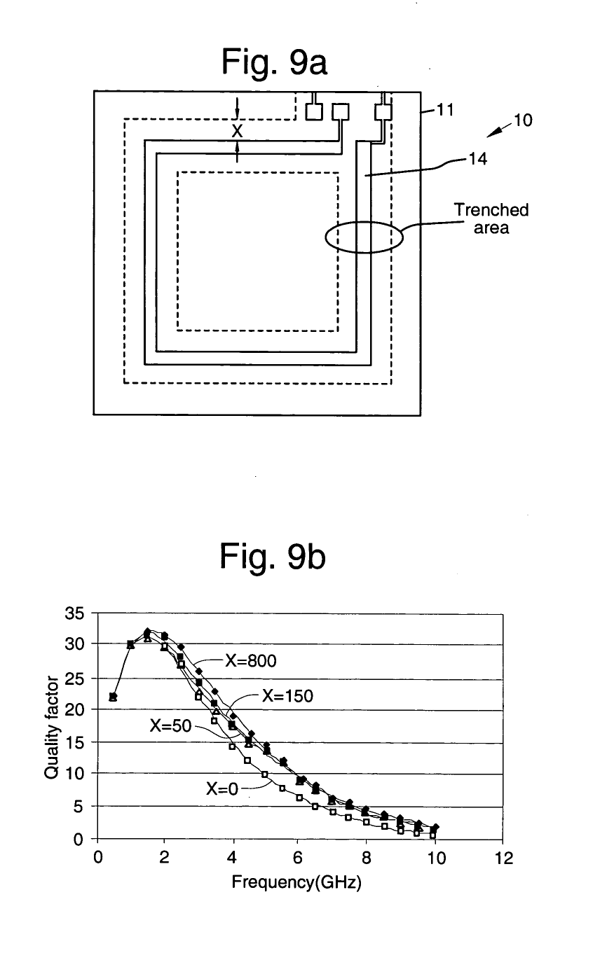

Another result extracted from measurements is the dependency of Q on the trenched area. FIG. 9a is a top view of another exemplary one turn inductor 14 formed on top of a perforated silicon substrate 11. The trenches are formed within the boundary of he dashed lines shown in FIG. 9a. FIG. 9b is a graph showing measured Q versus frequency for the exemplary inductor 14 shown in FIG. 9a. As is shown in FIG. 9b a negligible difference in Q has been observed when the trenched area is extended beyond 50 μm from the edge of the Cu tracks (X>50 μm in FIG. 9a), alleviating the need for trenching the entire area beneath the inductor.

The above discussion addresses the effect that trenching of a substrate 11 that supports an inductor 14 has on the inductor's 14 quality factor. The trenched area is covered or filled with a low-loss dielectric material 15 to provide a solid low-loss support for the inductors 14. Therefore, Q of the inductors 14 on this micromachined substrate 11 is less affected by the packaging material compared to conventional suspended inductors. Also, the capacitive loss of pads is simultaneously reduced, resulting in high de-embedded Q for inductors 14 on perforated silicon substrate 11. The height and width of the trenches 12a as well as the trenched area are characterized by fabricating several spiral type inductors 14 on perforated silicon substrate 11. Comparisons of the quality factor of the inductors 14 on perforated silicon substrate 11 and the Q's of identical inductors on other types of micromachined substrates 11 including oxide islands shows the remarkable effect of trenching the silicon substrate 11 in improving the performance of inductors 14 at radio frequencies.

Thus, high-Q integrated Cu inductors 14 on CMOS-grade silicon substrates 11 using a fully CMOS-compatible process has been disclosed. A fabrication sequence is used to reduce the loss of silicon substrate 11 at RF frequencies by trenching the substrate 11. Two approaches may be used to cover the trenches 12a and make a smooth surface. In one exemplary embodiment, high aspect-ratio (30:1) trenches 12a may be bridged-over by depositing a thin bridging layer 13 (˜3 m) of SiO₂ at 300° C., for example. In another exemplary embodiment, the trenches 12a are refilled by spin-coating of Avatrel polymer material 15. Metal loss of the inductors 14 was reduced by electroplating a thick (˜20 μm) Cu metallization layer 16a.

Comparing the measured Q of identical inductors 14 on different type of micromachined substrates 11 revealed that the perforated silicon substrate 11 (without refilling) exhibits the lowest-loss compared to other low-temperature micromachined silicon substrates 11. Measurement results indicate a significant improvement in the Q for inductors on perforated silicon substrate 11 compared to inductors fabricated on conventional standard silicon substrates.

Thus, low loss substrates that permit fabrication of high quality factor (Q) components thereon and related fabrication methods have been disclosed. It is to be understood that the above-described embodiments are merely illustrative of some of the many specific embodiments that represent applications of the principles disclosed herein. Clearly, numerous and other arrangements can be readily devised by those skilled in the art without departing from the scope of the invention.

What is claimed is:

1. Apparatus comprising:
a substrate having one or more cavities disposed adjacent a top surface thereof that define support elements in the substrate material;
a bridging layer formed on top of the top surface of the substrate that is supported by the support elements; and
a component formed on top of the bridging layer.

2. The apparatus recited in claim 1 wherein the one or more cavities are defined by one or more trenches in the substrate.

3. The apparatus recited in claim 1 wherein the plurality of support elements comprise pillars formed in the substrate.

4. The apparatus recited in claim 1 further comprising dielectric material disposed in the one or more cavities.

5. The apparatus recited in claim 1 wherein the bridging layer comprises a dielectric material.

6. The apparatus recited in claim 1 wherein the support elements are formed only under the component.

7. The apparatus recited in claim 1 wherein the substrate is selected from a group including silicon and glass, ceramic, silicon carbide, sapphire, organic and polymer.

8. The apparatus recited in claim 1 wherein the component is fixed or movable and is selected from a group including inductors, transmission lines, filters, antennas, micromechanical switches, transformers, tunable capacitors, fixed capacitors, and baluns.

9. The apparatus recited in claim 1 wherein at least a portion of the component is suspended above the bridging layer.

10. The apparatus recited in claim 1 wherein some of the support elements are removed after the bridging layer is formed.

11. The apparatus recited in claim 1 wherein the substrate is a multilayer substrate.

12. The apparatus recited in claim 1 wherein the component is encapsulated by a cover that does not touch the component.

13. A method comprising:
fabricating a substrate having one or more cavities disposed adjacent a top surface thereof that define support elements in the substrate material;
forming a bridging layer on a top surface of the substrate that is supported by the support elements; and
forming a component on top of the bridging layer.

14. The method recited in claim 13 wherein the one or more cavities are defined by one or more trenches in the substrate.

15. The method recited in claim 13 wherein the plurality of support elements comprise pillars formed in the substrate.

16. The method recited in claim 13 further comprising depositing dielectric material in the one or more cavities.

17. The method recited in claim 13 wherein support elements are formed only under the component.

18. The method recited in claim 13 wherein a suspended component is formed by:
forming a conductive layer on top of the bridging layer;
forming a sacrificial layer on top of the bridging layer and conductive layer;
forming a second conductive layer on top of the sacrificial layer; and
removing the sacrificial layer to suspend part of the second conductive layer.

19. A method of fabricating a component having a relatively high quality factor, comprising:
etching deep high-aspect-ratio cavities into a substrate to create a plurality of support elements that lowers substrate parasitic capacitance and disrupts dissipative currents that occur in the substrate;
depositing a bridging layer to bridge over the cavities;
forming a conductive layer on the bridging layer to provide the component.

20. The method recited in claim 19 wherein some of the support elements are removed after the bridging layer is formed.
